(19) United States
(12) Patent Application Publication
(10) Pub. No.: US 2007/0096287 A1
(43) Pub. Date: May 3, 2007

(54) Semiconductor device and a method of manufacturing the same

(76) Inventors: Makoto Araki, Tokyo (JP); Masakatsu Goto, Tokyo (JP); Shigeru Nakamura, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/582,328

(22) Filed: Oct. 18, 2006

(30) Foreign Application Priority Data
Oct. 27, 2005 (JP) 2005-312116

(51) Int. Cl. H01L 23/02

(52) U.S. Cl. 257/686

(57) ABSTRACT

Packaging performance of a semiconductor device is improved. A semiconductor device has a package substrate having a base material formed of resin; a semiconductor chip mounted on a main surface of the package substrate; a tape substrates being stacked on the package substrate in several stages, and electrically connected to a substrate at a lower stage via a plurality of solder balls; a second-stage chip, third-stage chip, and fourth-stage chip mounted on the tape substrates at respective stages; and a plurality of solder balls provided on a back surface of the package substrate; wherein a sealing body, which resin-seals the semiconductor chip and is formed by resin molding, is formed on a main surface of a package substrate disposed at the lowest stage, and the sealing body is disposed between the package substrate at the lowest stage and the tape substrate stacked thereon.

### CROSS-REFERENCE TO RELATED APPLICATIONS

The disclosure of Japanese Patent Application No. 2005-312116 filed on Oct. 27, 2005 including the specification, drawings and abstract is incorporated herein by reference in its entirety.

### BACKGROUND OF THE INVENTION

1. Field of the Invention

The present invention relates to a semiconductor device, and particularly relates to an effective technique for use in a semiconductor device having a structure of stacking semiconductor packages in multiple stages.

2. Description of Related Art

A technique is given, which includes a multilayer substrate, a first-stage chip electrically connected to the multilayer substrate, different package substrates stacked on the multilayer substrate in three stages, each of which is connected to a wiring substrate at a lower stage via solder balls respectively, a second-stage chip, third-stage chip, and fourth-stage chip mounted on the different package substrates stacked in three stages in an electrically connected manner respectively, and a plurality of solder balls provided on the multilayer substrate at the lowest layer (for example, refer to patent literature 1).

Patent literature 1: JP-A-2005-39020 (FIG. 6)

In assembling a package having a structure where a plurality of semiconductor chips are mounted in a semiconductor package (semiconductor device) , individual semiconductor chips sorted by a test are stacked for assembling.

In this case, when one of the semiconductor chips is determined as a bad chip, for example, in a burn-in test after assembling the package, the semiconductor package as a whole is regarded as a bad package. Therefore, when the number of semiconductor chips to be mounted is increased, KGDs (Known Good Dies) as good chips are more necessary.

In a semiconductor package known as SIP (System In Package) in which a logic chip and a memory chip are combined, wire bonding connection or layout of wiring on an interposer (substrate) is restricted. Furthermore, when a chip having the same size or a larger size is stacked at an upper stage, a method of stacking chips is restricted, for example, a spacer is required between chips, consequently stacking is often difficult.

Thus, in a technique, sorted semiconductor packages are stacked for assembling as in the patent literature 1 (JP-A-2005-39020).

As a result of investigation of a package structure described in the patent literature 1, the inventors found the following difficulties.

That is, it was found that in the package structure described in the patent literature 1, since a glass epoxy substrate was used for a wiring substrate at a first stage (the lowest stage), there was a difficulty of occurrence of warp due to difference in thermal expansion coefficient between the wiring substrate and a semiconductor chip to be mounted. When warp occurs in the glass epoxy substrate at the first stage, packaging is affected by the warp in the second stage or later, consequently packaging in the second stage or later becomes difficult.

Furthermore, it was found that since there were air gaps between respective stacked chips (between the packages), heat generated from the respective chips had no radiation path except for being transferred via solder balls disposed in the peripheries of the chips, consequently a difficulty of bad heat radiation was given. In particular, semiconductor chips at second to fourth stages are sandwiched by substrates at upper and lower surfaces of the chips, and furthermore the peripheries of the semiconductor chips are surrounded by the solder balls respectively, therefore heat generated from the semiconductor chips is easily accumulated, consequently heat radiation of the chips need to be improved.

### SUMMARY OF THE INVENTION

It is desirable to provide a technique by which packaging performance of a semiconductor device can be improved.

Furthermore, it is desirable to provide a technique by which heat radiation of the semiconductor device can be improved.

The foregoing and other desirableness and novel features of an embodiment of the invention will be clarified according to description of the specification and accompanied drawings.

Among inventions disclosed in the application, summaries of typical inventions are briefly described as follows.

That is, an embodiment of the invention provides a semiconductor device including a wiring substrate, a semiconductor chip mounted on the wiring substrate, a first sealing body for sealing the semiconductor chip, a plurality of first ball electrodes provided on a back surface of the wiring substrate, a tape substrate, a different semiconductor chip mounted on the tape substrate, a second sealing body being filled into a space between a main surface of the tape substrate and a main surface of the different semiconductor chip, and having low viscosity compared with the first sealing body, and a plurality of second ball electrodes provided on a back surface of the tape substrate; wherein the tape substrate is stacked on the wiring substrate via the plurality of second ball electrodes in one or several stages.

Moreover, another embodiment of the invention provides a method of manufacturing a semiconductor device including a step of assembling a first semiconductor package; a step of assembling a second semiconductor package; a step of stacking second semiconductor packages as good packages on a first semiconductor package as a good package in one or several stages via a plurality of second ball electrodes on which solder paste was transferred respectively; and a step of melting the solder paste in the second semiconductor package at each stage by collective reflow, thereby connecting between the plurality of second ball electrodes and a plurality of electrodes formed on main surfaces of multiple tape substrates at a lower stage with respect to the second ball electrodes, or a plurality of electrodes formed on a main surface of a multi package substrate.

Among inventions disclosed in the application, advantages obtained by typical inventions are briefly described as follows.

A sealing body formed by resin molding is formed on a wiring substrate at the lowest stage, thereby a curing shrinkage effect of sealing resin occurs during the resin molding, and thus warp of the wiring substrate can be reduced. As a result, packaging performance can be improved in stacking of packages. Moreover, a film member is disposed on a surface of the sealing body on the wiring substrate at the lowest stage, or a back surface of a different semiconductor chip of a package stacked on the wiring substrate; thereby heat generated from the different semiconductor chip of the package stacked at an upper stage can be transferred to a package at a lower stage via the film member. As a result, heat radiation of a semiconductor device can be improved.

### BRIEF DESCRIPTION OF THE DRAWINGS

FIG. 1 shows a cross section view and an enlarged partial section view, showing an example of a structure of a semiconductor device of an embodiment of the invention;

FIG. 2 shows an enlarged partial section view showing an example of thickness of each package of the semiconductor device shown in FIG. 1;

FIG. 3 shows a data diagram showing an example of a numeral value of thickness of each member of the structure shown in FIG. 2;

FIG. 4 shows a plane view showing an example of a chip layout of a first semiconductor package at a first stage of the semiconductor device shown in FIG. 1;

FIG. 5 shows a plane view showing an example of a chip layout of a second semiconductor package at a second stage of the semiconductor device shown in FIG. 1;

FIG. 6 shows a plane view showing an example of a chip layout of second semiconductor packages at third and fourth stages of the semiconductor device shown in FIG. 1;

FIG. 7 shows a cross section view showing an example of a condition of resin curing shrinkage during resin molding in assembling the semiconductor device shown in FIG. 1;

FIG. 8 shows a plane view and a partial section view showing an example of a structure of a tape substrate used for the second semiconductor package of the semiconductor device shown in FIG. 1, and further shows a plane view and a partial section view of a tape substrate of a comparative example;

FIG. 9 shows a plane view showing an example of a structure of a surface of a tape substrate used for the second semiconductor package of the semiconductor device shown in FIG. 1;

FIG. 10 shows a cross section view showing an example of a structure exhibiting a stress relief effect in the semiconductor device shown in FIG. 1;

FIG. 11 shows a structural view showing a structure of a radiation path when the semiconductor chip at the first stage generates heat in the semiconductor device shown in FIG. 1, and an example of a model structure for calculating heat resistance of the radiation path;

FIG. 12 shows a data diagram showing an example of a simulation result of heat resistance in the case that an adhesive is included in the structure shown in FIG. 11;

FIG. 13 shows a data diagram showing an example of a simulation result of heat resistance in the case that the adhesive is not included in the structure shown in FIG. 11;

FIG. 14 shows a structural view showing a structure of a radiation path when the semiconductor chip at the third stage generates heat in the semiconductor device shown in FIG. 1, and an example of a model structure for calculating heat resistance of the radiation path;

FIG. 15 shows a data diagram showing an example of a simulation result of heat resistance in a vertical direction of a chip in the case that the adhesive is included in the structure shown in FIG. 14;

FIG. 16 shows a data diagram showing an example of a simulation result of heat resistance of an electrode part in the case that the adhesive is included in the structure shown in FIG. 14;

FIG. 17 shows a data diagram showing an example of a simulation result of heat resistance in a vertical direction of a chip in the case that the adhesive is not included in the structure shown in FIG. 14;

FIG. 18 shows a data diagram showing an example of a simulation result of heat resistance of the electrode part in the case that the adhesive is not included in the structure shown in FIG. 14;

FIG. 19 shows a side view showing an example of a position of a thermal via hole in the semiconductor device shown in FIG. 1;

FIG. 20 shows a plane view showing an example of a position of a thermal via hole in a wiring substrate used for the first semiconductor package at the first stage of the semiconductor device shown in FIG. 19;

FIG. 21 shows a process flow diagram and cross section views showing an example of a procedure of assembling the first semiconductor package of the semiconductor device shown in FIG. 1;

FIG. 22 shows a process flow diagram and cross section views showing a solder ball supply step and steps before it in an example of a procedure of assembling the second semiconductor package of the semiconductor device shown in FIG. 1;

FIG. 23 shows a process flow diagram and a cross section view showing a sorting step and steps thereafter in an example of a procedure of assembling the second semiconductor package of the semiconductor device shown in FIG. 1;

FIG. 24 shows a process flow diagram and cross section views showing a stacking step and steps before it in an example of a procedure of stacking the first semiconductor package and the second semiconductor packages in assembling the semiconductor device shown in FIG. 1; and

FIG. 25 shows a process flow diagram and cross section views showing a reflow step and steps thereafter in an example of a procedure of stacking the first semiconductor package and the second semiconductor packages in assembling the semiconductor device shown in FIG. 1.

### DESCRIPTION OF THE PREFERRED EMBODIMENT

In the following embodiment, the same or similar portions are not repeatedly described in principle unless they are particularly necessary to be described.

Furthermore, while the following embodiment is described dividedly into several sections or embodiments if it is necessary for convenience, they are not independent of one another, for example, one may be a modification, detail, or supplementary explanation of the other.

Moreover, when the following embodiment refers to the number of elements (including number of pieces, numeral values, quantity, and range), the number is not limited to such a specific number except for the case that it is particularly demonstrated, and the case that it is principally obviously limited to a particular number, and may be the particular number or more, or less.

Hereinafter, the embodiment of the invention will be described in detail according to drawings. Members having the same function are marked with the same signs in all figures for describing the embodiment, and omitted to be repeatedly described.

Embodiment

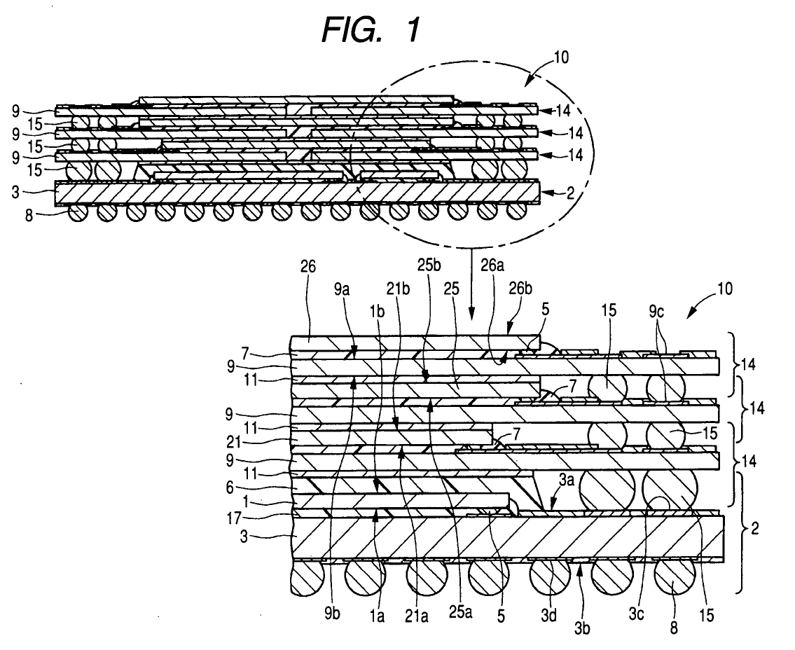

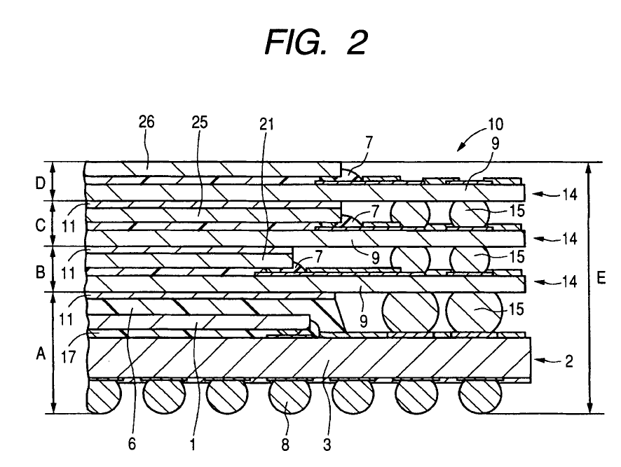

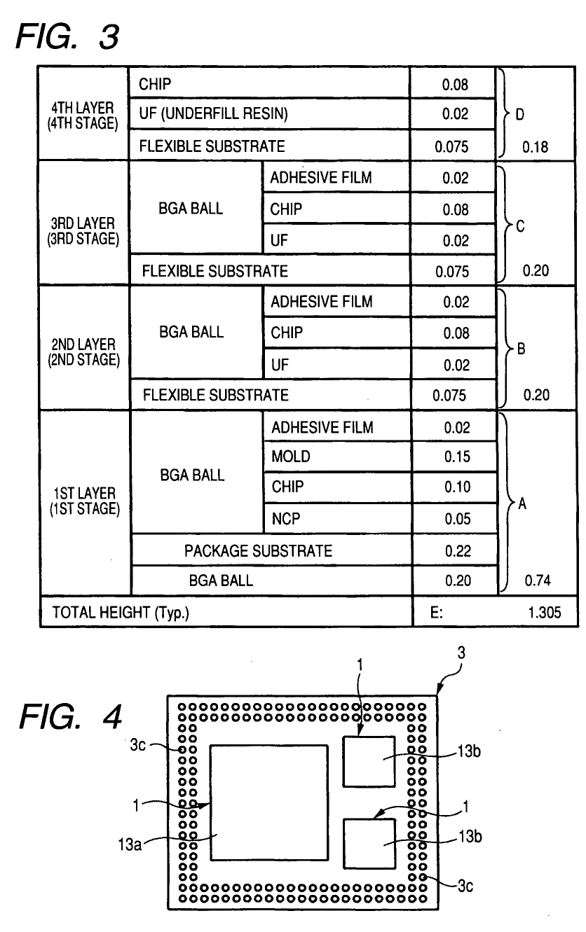

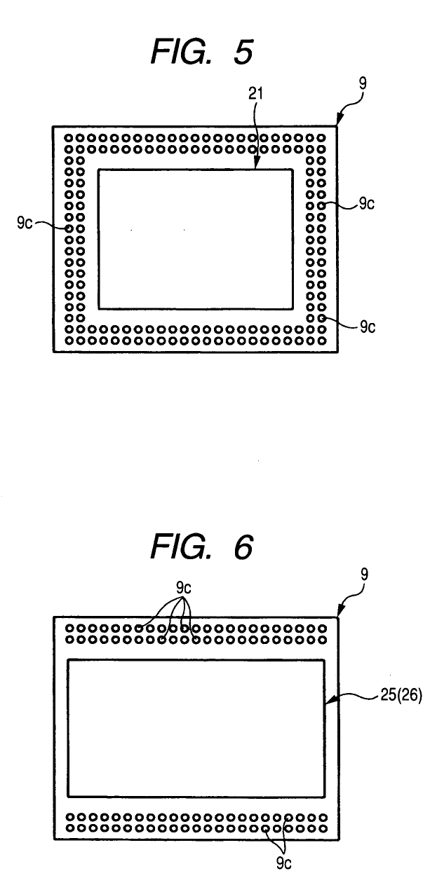

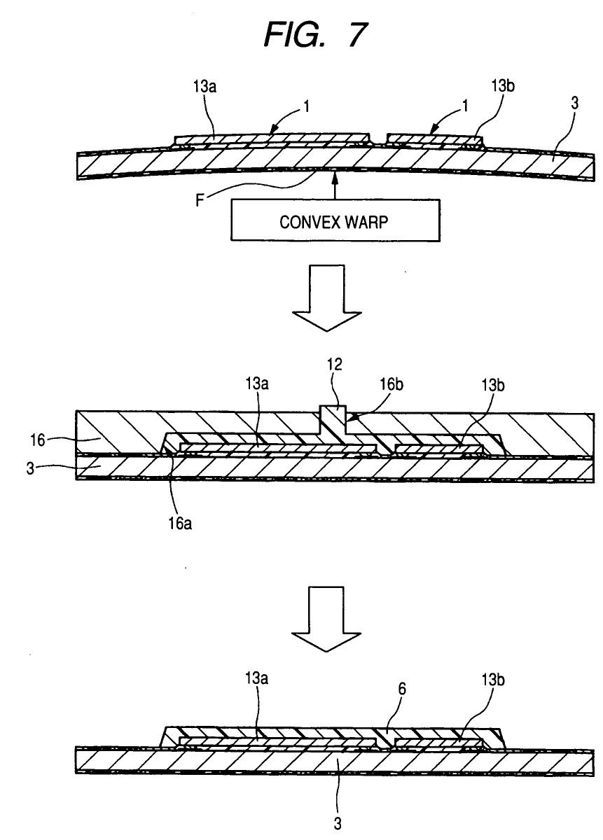

FIG. 1 shows a cross section view and an enlarged partial section view, showing an example of a structure of a semiconductor device of the embodiment of the invention, FIG. 2 shows an enlarged partial section view showing an example of thickness of each package of the semiconductor device shown in FIG. 1, FIG. 3 shows a data diagram showing an example of a numeral value of thickness of each member of the structure shown in FIG. 2, and FIG. 4 shows a plane view showing an example of a chip layout of a first semiconductor package at a first stage of the semiconductor device shown in FIG. 1. Furthermore, FIG. 5 shows a plane view showing an example of a chip layout of a second semiconductor package at a second stage of the semiconductor device shown in FIG. 1, FIG. 6 shows a plane view showing an example of a chip layout of second semiconductor packages at third and fourth stages of the semiconductor device shown in FIG. 1, and FIG. 7 shows a cross section view showing an example of a condition of resin curing shrinkage during resin molding in assembling the semiconductor device shown in FIG. 1.

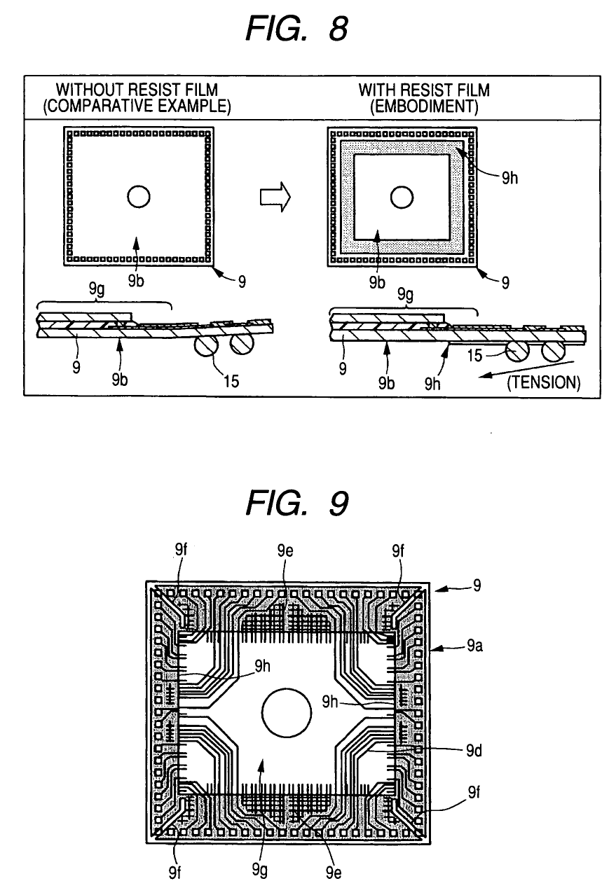

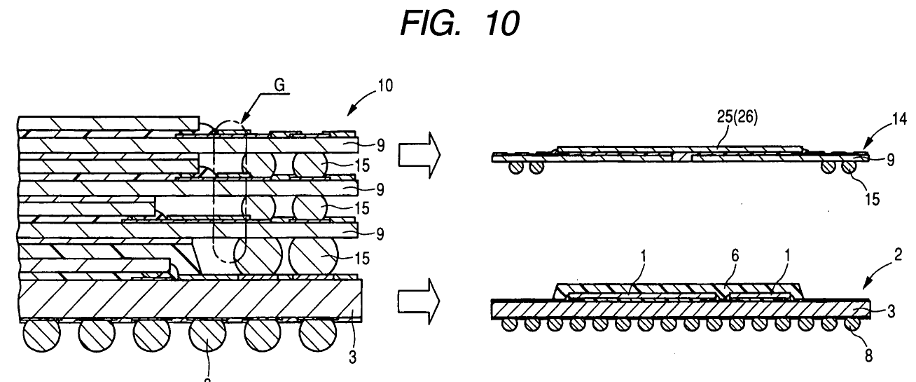

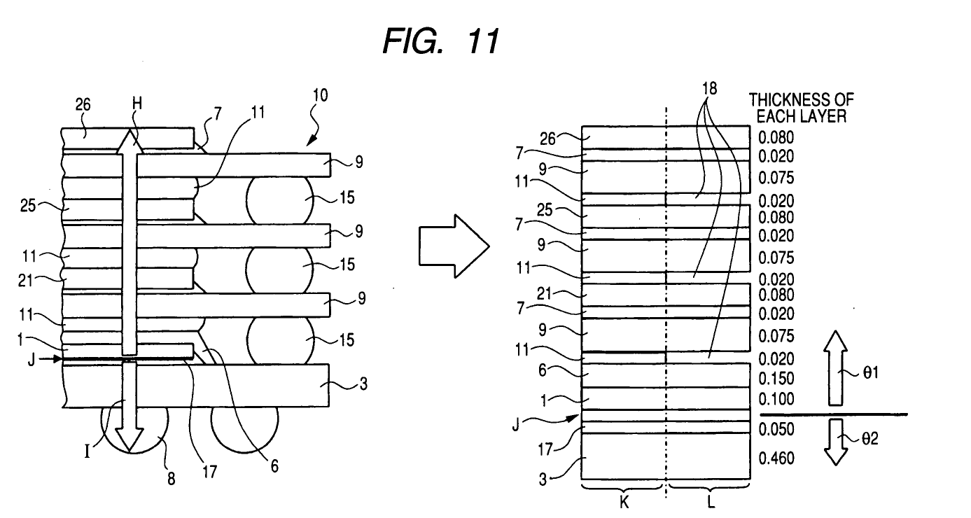

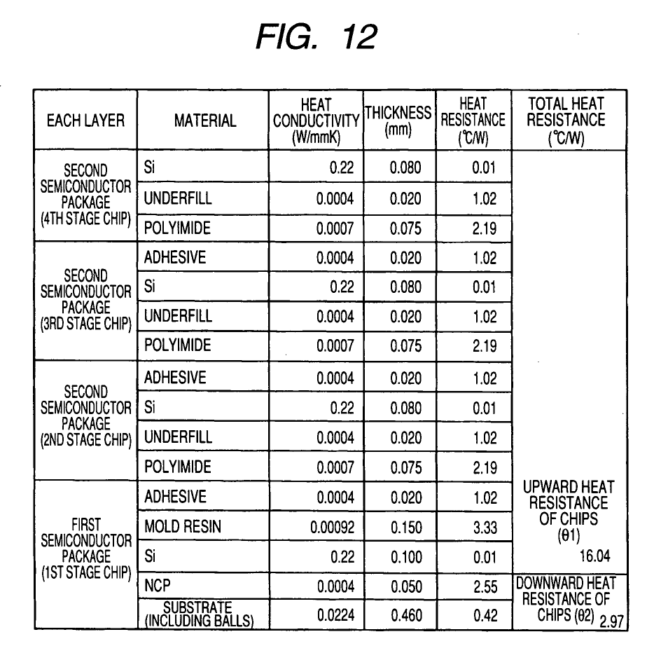

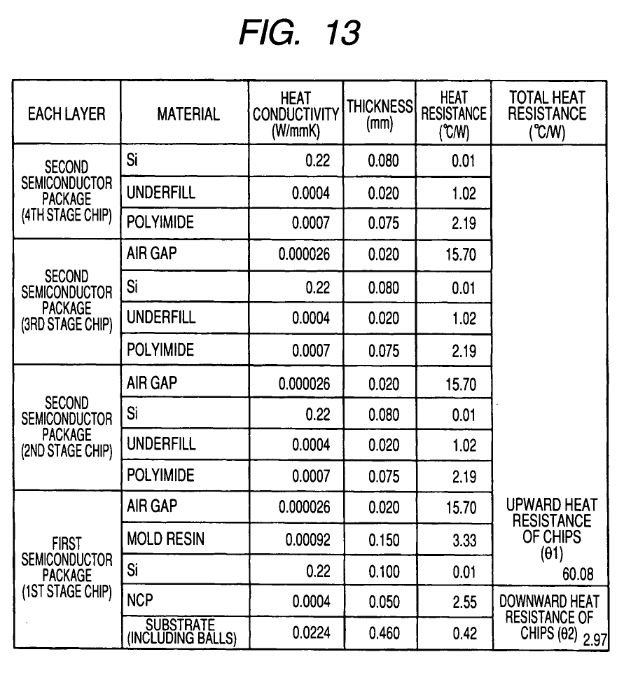

FIG. 8 shows a plane view and a partial section view showing an example of a structure of a tape substrate used for the second semiconductor package of the semiconductor device shown in FIG. 1, and further shows a plane view and a partial section view of a tape substrate of a comparative example, FIG. 9 shows a plane view showing an example of a structure of a surface of a tape substrate used for the second semiconductor package of the semiconductor device shown in FIG. 1, and FIG. 10 shows a cross section view showing an example of a structure having a stress relief effect in the semiconductor device shown in FIG. 1. Furthermore, FIG. 11 shows a structural view showing a structure of a radiation path when the semiconductor chip at the first stage generates heat in the semiconductor device shown in FIG. 1, and an example of a model structure for calculating heat resistance of the radiation path, FIG. 12 shows a data diagram showing an example of a simulation result of heat resistance in the case that an adhesive is included in the structure shown in FIG. 11, and FIG. 13 shows a data diagram showing an example of a simulation result of heat resistance in the case that the adhesive is not included in the structure shown in FIG. 11.

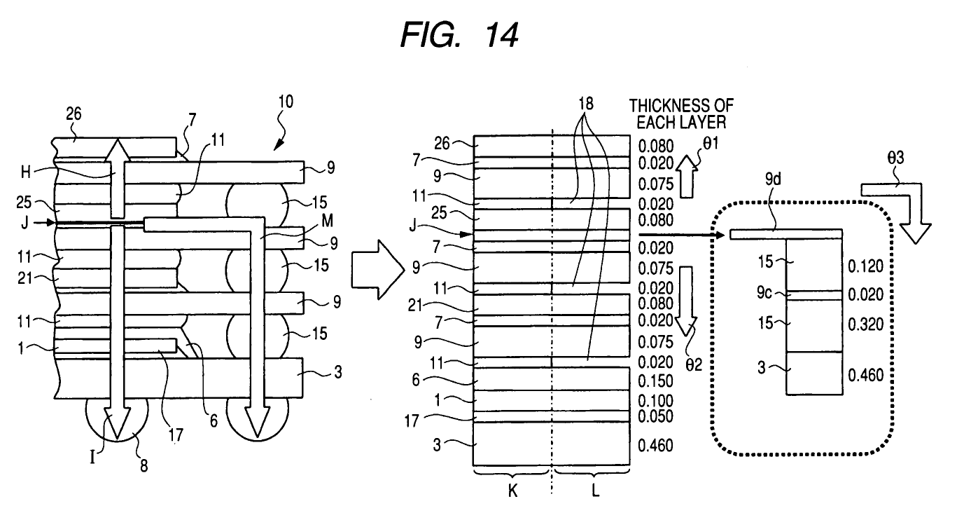

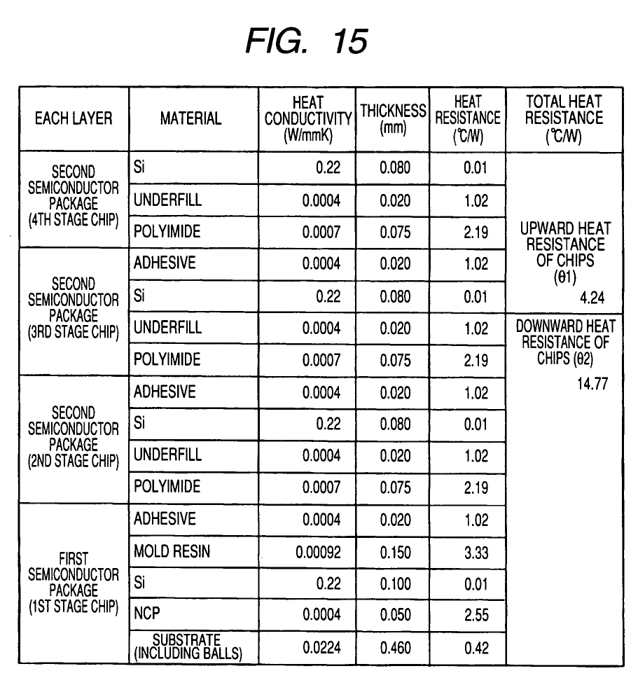

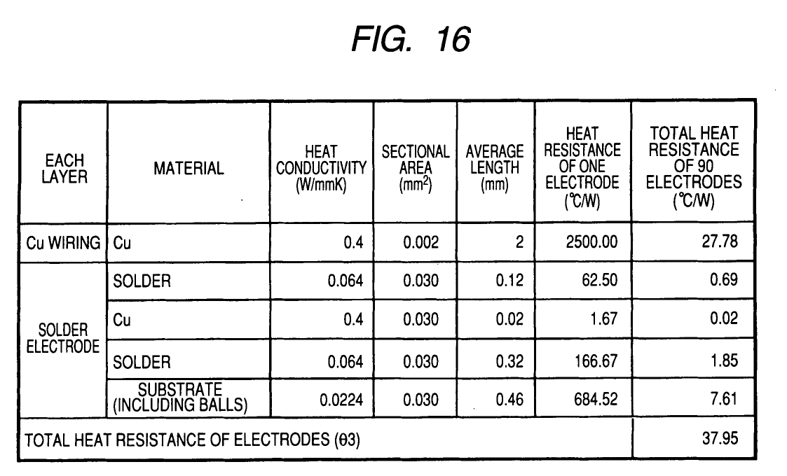

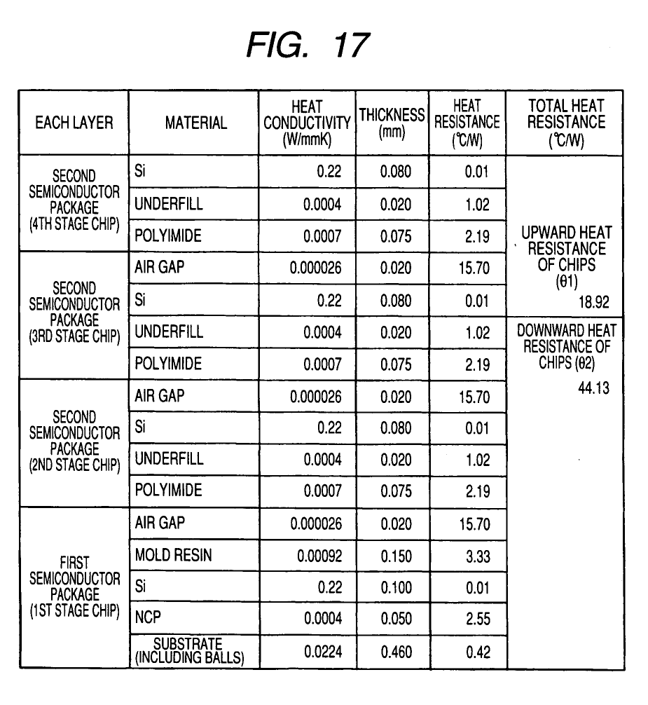

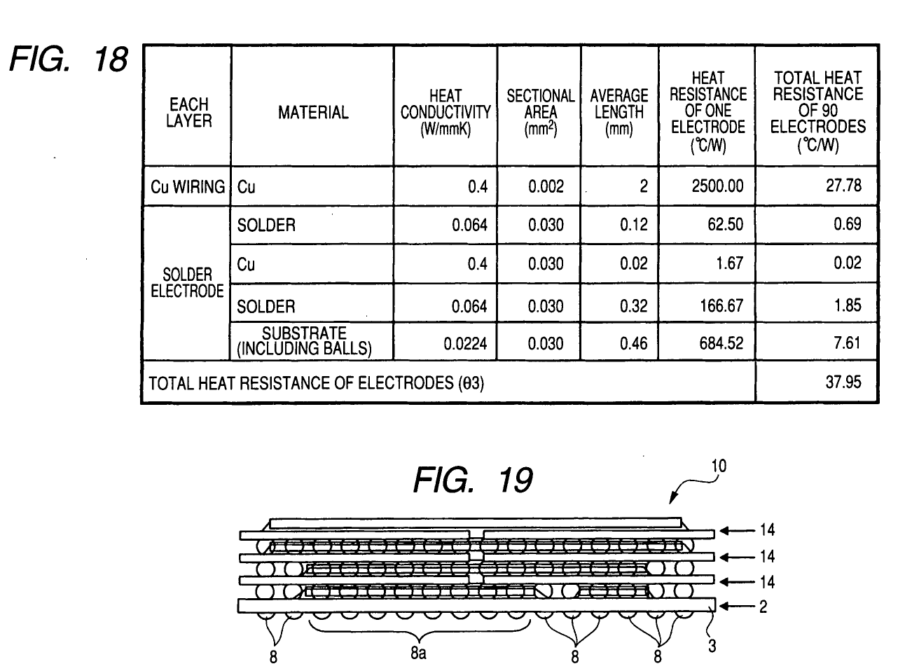

FIG. 14 shows a structural view showing a structure of a radiation path when the semiconductor chip at the third stage generates heat in the semiconductor device shown in FIG. 1, and an example of a model structure for calculating heat resistance of the radiation path, FIG. 15 shows a data diagram showing an example of a simulation result of heat resistance in a vertical direction of a chip in the case that the adhesive is included in the structure shown in FIG. 14, and FIG. 16 shows a data diagram showing an example of a simulation result of heat resistance of an electrode part in the case that the adhesive is included in the structure shown in FIG. 14. Furthermore, FIG. 17 shows a data diagram showing an example of a simulation result of heat resistance in a vertical direction of a chip in the case that the adhesive is not included in the structure shown in FIG. 14, FIG. 18 shows a data diagram showing an example of a simulation result of heat resistance of the electrode part in the case that the adhesive is not included in the structure shown in FIG. 14, and FIG. 19 shows a side view showing an example of a position of a thermal via hole in the semiconductor device shown in FIG. 1.

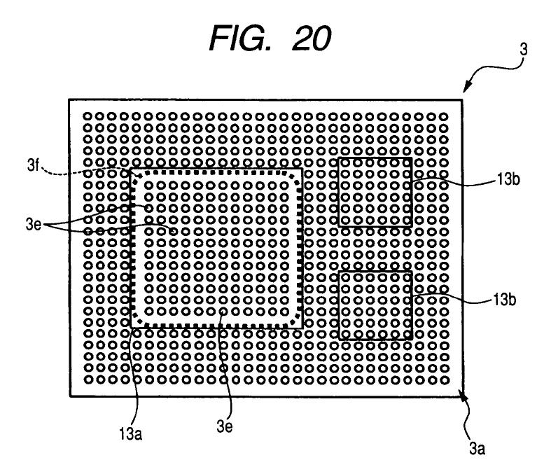

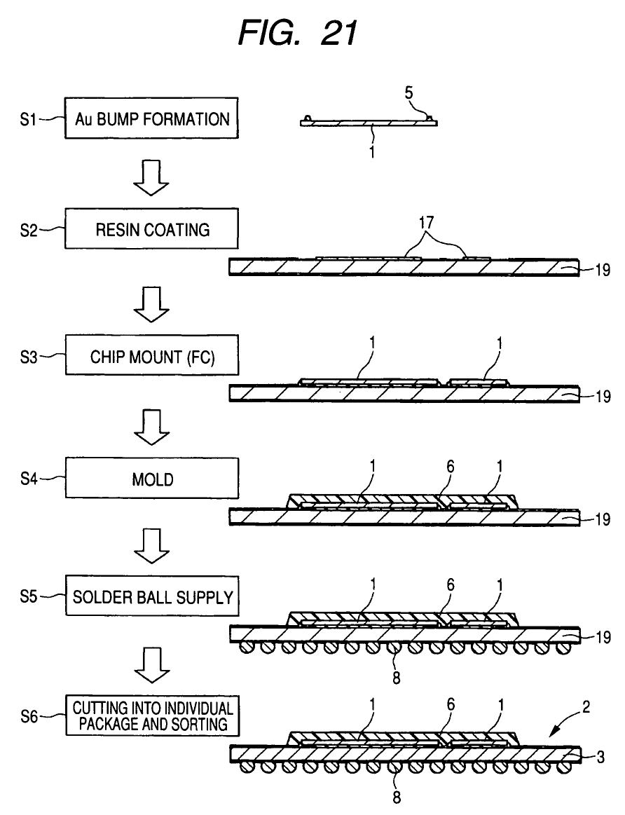

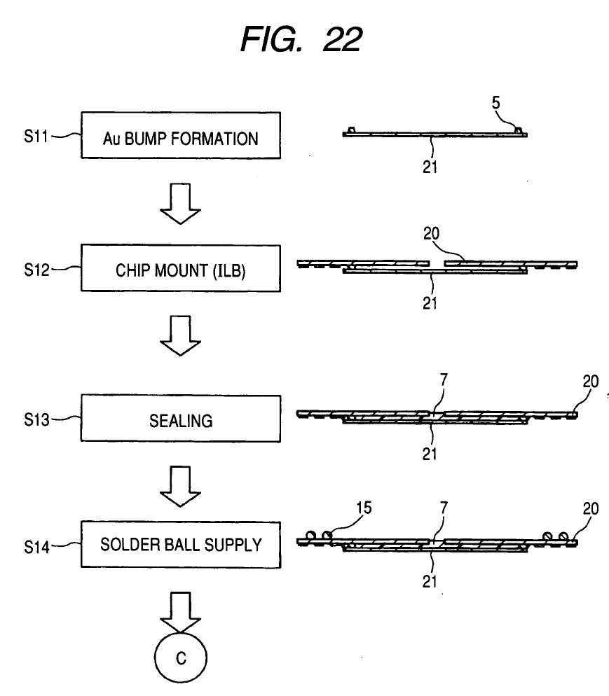

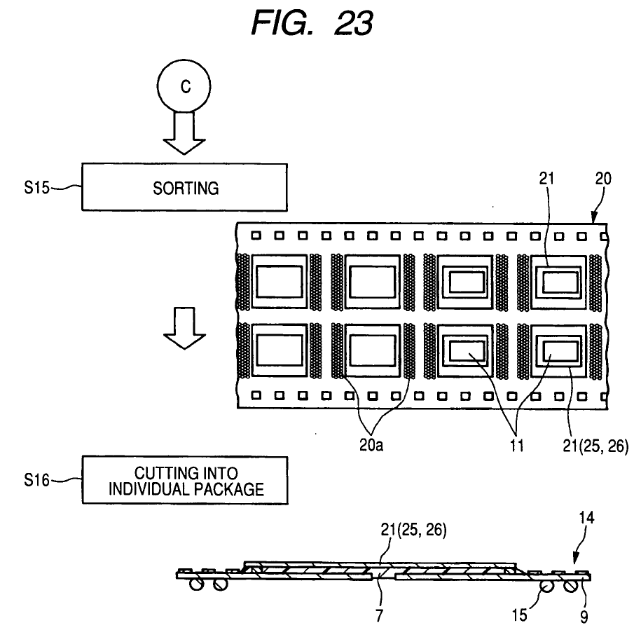

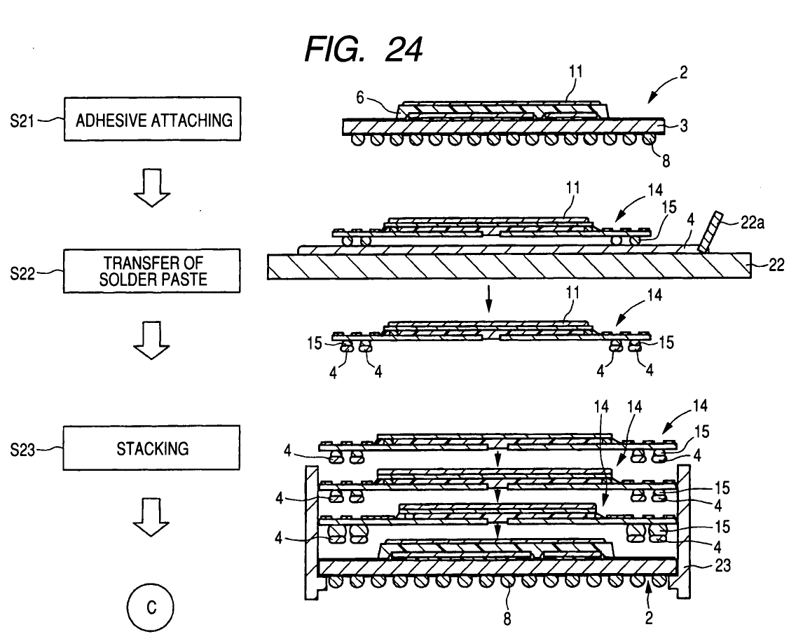

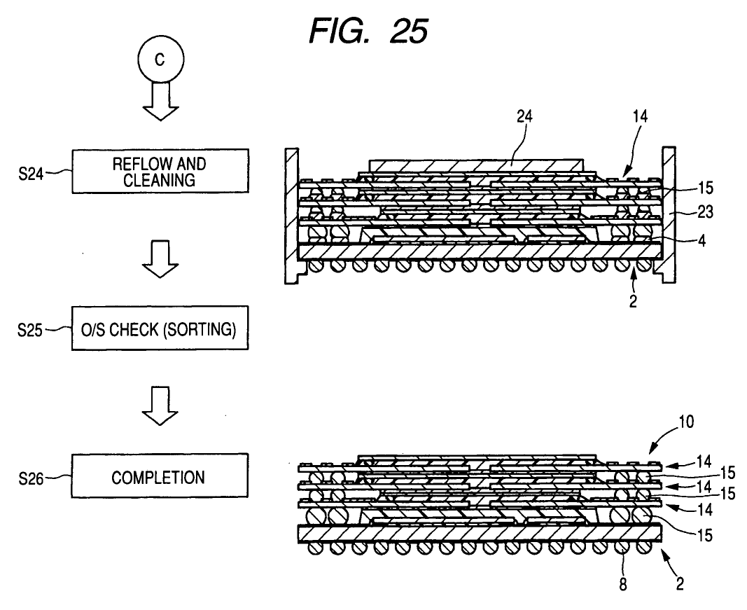

FIG. 20 shows a plane view showing an example of a position of a thermal via hole in a wiring substrate used for the first semiconductor package at the first stage of the semiconductor device shown in FIG. 19, FIG. 21 shows a process flow diagram and cross section views, showing an example of a procedure of assembling the first semiconductor package of the semiconductor device shown in FIG. 1, and FIG. 22 shows a process flow diagram and cross section views showing a solder ball supply step and steps before it in an example of a procedure of assembling the second semiconductor package of the semiconductor device shown in FIG. 1. Furthermore, FIG. 23 shows a process flow diagram and a cross section view showing a sorting step and steps thereafter in an example of a procedure of assembling the second semiconductor package of the semiconductor device shown in FIG. 1, and FIG. 24 shows a process flow diagram and cross section views showing a stacking step and steps before it in an example of a procedure of stacking the first semiconductor package and the second semiconductor packages in assembling the semiconductor device shown in FIG. 1. FIG. 25 shows a process flow diagram and cross section views showing a reflow step and steps thereafter in an example of a procedure of stacking the first semiconductor package and the second semiconductor packages in assembling the semiconductor device shown in FIG. 1.

The semiconductor device according to the embodiment of the invention is mounted in a mobile electronic instrument such as mobile phone, and is a stacked package 10 sometimes called POP (Package On Package) in which a semiconductor package is stacked with a different semiconductor package. That is, in the semiconductor device, second semiconductor packages 14, which have small thickness compared with a first semiconductor package 2, are stacked in several stages on the first semiconductor package 2 in a BGA (Ball Grid Array) type at the lowest stage as shown in FIG. 1. In the embodiment, the stacked package 10 having a four-layer structure including the first semiconductor package 2 at the first stage, and the second semiconductor packages 14 stacked at second to fourth stages is described as an example.

The first semiconductor package 2 at the lowest stage (first stage) has a package substrate 3 as a wiring substrate having a main surface 3a and a back surface 3b opposed to the main surface, and having a base material formed of resin such as glass epoxy series resin. That is, the package substrate 3 is a multilayer organic substrate.

Solder balls (first ball electrodes) 8 as a plurality of ball electrodes are provided in a lattice pattern as outer terminals on the back surface 3b of the package substrate 3. The solder balls 8 are connected to lands 3d on the back surface 3b of the package substrate 3.

A semiconductor chip 1 is mounted on the main surface 3a of the package substrate 3, the chip being electrically connected to the main surface via gold bumps 5 by flip-chip connection. In the embodiment, as shown in FIG. 4, an example where three semiconductor chips 1 in different size are mounted on the package substrate 3 is described. One large semiconductor chip 1 mounted on the package substrate 3 is, for example, a many-pin DSP chip 13a having a DSP (Digital Signal Processing) circuit, and two small semiconductor chips 1 are, for example, analog chips 13b having a linear logic circuit.

As shown in FIG. 1, the three semiconductor chips 1 in different size are resin-sealed on the package substrate 3, and covered with a sealing body (first sealing body) 6 formed by resin molding. The sealing body 6 includes, for example, thermosetting epoxy series resin. The sealing body 6 is formed in a region inside a plurality of electrodes 3c provided on the package substrate 3. The reason for forming the sealing body 6 only near the center of the package substrate 3 where the semiconductor chips are mounted is described later. NCP (Non-Conductive Paste) 17 or underfill resin (second sealing body) 7 is disposed in each flip-chip connection portion of the first semiconductor package 2. Since the semiconductor chip 1 is mounted on the package substrate 3 by the flip-chip connection, a space between the main surface 1a of the semiconductor chip 1 and the main surface 3a of the package substrate 3 is very narrow. Therefore, NCP 17 or underfill resin 7 having low viscosity compared with the sealing body 6 is preferably used for a material to be filled into the space between the main surface 1a of the semiconductor chip 1 and the main surface 3a of the package substrate 3. Thus, insufficient filling can be suppressed. On the other hand, each of the second semiconductor packages 14 at second to fourth stages has a main surface 9a and a back surface 9b opposed to the main surface, and has a flexible tape substrate 9.

A second-stage chip 21, third-stage chip 25, and fourth-stage chip 26 as different semiconductor chips are mounted on main surfaces 9a of respective tape substrates 9, each of the semiconductor chips being electrically connected to the main surface 9a via the gold bumps 5 by the flip-chip connection, and each flip-chip connection portion is filled with NCP 17 or underfill resin (second sealing body) 7. The reason for this is the same as in the first semiconductor package 2. A main surface 21a of the second-stage chip 21, main surface 25a of the third-stage chip 25, and main surface 26a of the fourth-stage chip 26 are disposed in an opposed manner to the substrates respectively.

Solder balls (second ball electrodes) 15 as a plurality of ball electrodes are provided on a back surface 9b of the tape substrate 9 as outer terminals. As shown in FIG. 8, the plurality of solder balls 15 are provided, for example, in two lines on the periphery of a region outside an area of the back surface 9b corresponding to a chip region 9g of the main surface 9a. That is, the second semiconductor package 14 is a fan-out type package.

The stacked package 10 shown in FIG. 1 is formed by stacking the second semiconductor package 14 on the first semiconductor package 2, which is configured as above, and an example of the stacked package 10 of the embodiment shown in FIG. 1 has a four-stage package structure in which three, second semiconductor packages 14 are stacked on the first semiconductor package 2.

As outer connection terminals of the stacked package 10, the plurality of solder balls 8 provided on the back surface 3b of the package substrate 3 of the first semiconductor package 2 act as the terminals, and disposed in a lattice pattern on the back surface 3b of the package substrate 3.

Moreover, in the stacked package 10, the sealing body 6 of the first semiconductor package 2 is disposed between the package substrate 3 at the lowest stage and the tape substrate 9 of the second semiconductor package 14 at the second stage stacked thereon.

Moreover, in the semiconductor package 14 at the second stage or later in the stacked package 10, the solder balls 15 as outer terminals of each package are electrically connected to the electrode 3c or electrode 9c on a substrate at a lower stage. That is, since the second semiconductor package 14 is the fan-out type package, when the second semiconductor package 14 is stacked, the solder balls 15 on the back surface 9b of each tape substrate 9 can be connected to the electrode 3c or 9c provided in the periphery outside the chip mounting area in the main surface 3a or 9a of the substrate at a lower stage side of the solder balls.

Since the sealing body 6 is disposed between the package substrate 3 at the lowest stage and the tape substrate 9 of the second semiconductor package 14 at the second stage stacked thereon, solder balls 15 of the second semiconductor package 14 at the second stage are formed high compared with thickness of the sealing body 6, the package 14 being disposed between the package substrate 3 and the tape substrate 9 at the second stage stacked thereon. In other word, the solder balls 15 are formed large compared with solder balls 15 disposed at the third stage or later, or at an upper stage with respect to the solder balls 15 at the second stage. In further description, the plurality of second ball electrodes include solder balls (third ball electrodes) 15 electrically connected to the main surface 3a of the package substrate 3, and solder balls (fourth ball electrodes) 15 electrically connected to the main surface 9a of the package substrate 9, and the diameter of the third ball electrodes is formed large compared with the diameter of the fourth ball electrodes. On the other hand, solder balls 15 disposed at the third stage or later are formed low compared with the thickness of the sealing body 6.

That is, while the sealing body 6 covering the three semiconductor chips 1 in different size are disposed between the package substrate 3 at the first stage and the tape substrate 9 at the second stage, the sealing body 6 covering an area on a chip is not provided in the second semiconductor package 14 at the second stage or later, therefore a space between the tape substrates 9 is small at stages of the second stage or later compared with a space between the package substrate 3 at the first stage and the tape substrate 9 at the second stage. Therefore, the solder balls 15 of the second semiconductor package 14 at the second stage are formed large compared with solder balls 15 disposed at the third stage or later, or at an upper stage with respect to the solder balls 15 at the second stage.

Moreover, in the stacked package 10, an adhesive film (film member) 11 for heat radiation is provided on a surface of the sealing body 6 of the first semiconductor package 2 at the first stage, a back surface 21b of the second-stage chip 21 of the second semiconductor package 14 at the second stage, and a back surface 25b of the third-stage chip 25 of the second semiconductor package 14 at the third stage respectively. Therefore, the sealing body 6 of the first semiconductor package 2 at the first stage and the tape substrate 9 of the second semiconductor package 14 at the second stage, and the second-stage chip 21 of the second semiconductor package 14 at the second stage and the tape substrate 9 of the second semiconductor package 14 at the third stage, and furthermore the third-stage chip 25 of the second semiconductor package 14 at the third stage and the tape substrate 9 of the second semiconductor package 14 at the fourth stage are connected via the adhesive films 11 for heat radiation, respectively.

For example, the adhesive film 11 for heat radiation is an adhesive film including epoxy resin containing thermosetting conductive particles.

The stacked package 10 of the embodiment is, for example, a semiconductor package including DSP and a memory combined with each other. Therefore, a many-pin type DSP circuit is preferably incorporated in the semiconductor chip 1 of the first semiconductor package 2 having the multilayer organic substrate at the first stage. For example, in the first semiconductor package 2 of the stacked package 10, as shown in FIG. 4, the three semiconductor chips 1 in different size are mounted on the package substrate 3 of the package 2. In FIG. 4, for example, a DSP circuit is incorporated in one large semiconductor chip 1, and for example, a linear logic circuit is incorporated in two small semiconductor chips.

On the other hand, for example, a few-pin type memory circuit is incorporated in the second-stage chip 21, third-stage chip 25, and fourth-stage chip 26 as the different semiconductor chips of the second semiconductor packages 14 having the tape substrates 9 at an upper stage side of the stacked packages. For example, a nonvolatile memory circuit is incorporated in the second-stage chip 21, and a DRAM (Dynamic Random Access Memory) circuit is incorporated in the third-stage chip 25 and the fourth-stage chip 26. From the above, since the chip incorporated with the few-pin type memory circuit has few wiring lines at a mounting substrate side, the tape substrate 9 can be used for the chip. On the contrary, since the chip incorporated with the many-pin type DSP circuit has many wiring lines at the mounting substrate side compared with a case of the chip incorporated with the memory circuit, the multilayer organic substrate is used for the chip.

Next, thickness or size in a plane direction of the stacked package 10 is described using FIGS. 2 to 6.

First, thickness (height) of the stacked package 10 is described. An example of thickness of each member of the stacked package 10 is as shown in FIG. 3. When respective members are stacked, and height of the first semiconductor package 2 at the first stage and the package at the second stage or later is obtained respectively, the height (A) of the first semiconductor package 2 at the first stage is, for example, 0.74 mm.

On the other hand, thickness from the tape substrate 9 to the adhesive film 11 for heat radiation in each of the second semiconductor packages 14 at the second and third stages (B or C, except the solder balls 15) is, for example, 0.20 mm, and thickness from the tape substrate 9 to the back surface 26b of the fourth-stage chip 26 in the second semiconductor package 14 at the fourth stage is, for example, 0.18 mm.

Therefore, the total thickness (height) E (E=A+B+C+D) of the stacked package 10 is E=1.32 mm (typical value=1,305 mm), consequently the Max value of mounting height of the stacked package 10 can be suppressed to 1.40 mm even if tolerance or coplanarity is included. That is, reduction in thickness can be achieved in the stacked package 10.

Next, size in the planar direction of the stacked package 10 is described. As the size in the planar direction of the stacked package 10, size of the largest substrate in all the substrates to be stacked corresponds to the size in the planar direction of the stacked package 10. Furthermore, size of each substrate is associated with size of a chip to be mounted, and approximately 2 mm longer than size of the largest chip to be mounted.

Here, FIG. 4 shows size of the package substrate 3 at the first stage and the semiconductor chips 1 mounted on the substrate. In the semiconductor chips 1 at the first stage, a larger one is a DSP chip 13a, and a smaller one is an analog chip 13b. The DSP chip 13a is in a size of, for example, 7×7 mm, and on the other hand, the analog chip 13b is in a size of, for example, 3×3 mm. Therefore, the size of the package substrate 3 is 13×16 mm.

FIG. 5 shows size of the tape substrate 9 at the second stage and the second-stage chip 21. Since size of the second-stage chip 21 is 8×11 mm, size of the tape substrate 9 at the second stage is 13×16 mm.

Furthermore, FIG. 6 shows size of the tape substrates 9 at the third and fourth stages, and the third-stage chip 25 and the fourth-stage chip 26. Since size of the third-stage chip 25 and the fourth-stage chip 26 is 8.6×14.2 mm, size of the tape substrates 9 at the third and fourth stages is 13×16 mm.

In this way, in the stacked package 10 of the embodiment, size (8.6×14.2 mm) of the third-stage chip 25 and the fourth-stage chip 26 is largest among respective chips, and size of all the substrates is 13×16 mm in accordance with this.

Therefore, size in the planar direction of the stacked package 10 is also 13×16 mm.

Each chip is disposed such that a side of the substrate is approximately parallel to a side of the chip in each stage.

Next, a measure for warp of the stacked package 10 of the embodiment is described.

As shown in a portion F of FIG. 7, in the package substrate 3 after mounting the chip, since the substrate has high stiffness compared with the chip, warp occurs in a convex direction. Thus, in the stacked package 10 of the embodiment, the sealing body 6 covering the semiconductor chip 1 is formed by resin molding using a resin molding die 16 in a resin sealing step in assembling the first semiconductor package 2.

At that time, for example, thermosetting epoxy series resin (biphenyl series) containing filler is preferably used for sealing resin 12.

That is, the sealing body 6 is formed by resin molding in a transfer method using the resin molding die 16 and the sealing resin 12, thereby warp can be suppressed by curing shrinkage of the sealing resin 12 during curing. That is, an effect of curing shrinkage of the sealing resin 12 during curing is used to pull the package substrate 3 in a direction opposite to a warp direction by shrinkage force during curing shrinkage, as a result, the package substrate 3 can be controlled flat while it is clamped by the resin molding die 16, consequently warp of the package substrate 3 can be prevented.

At that time, physical properties of the sealing resin 12 are adjusted (the content of filler is adjusted) in accordance with change in substrate type, number of layers, and chip size, thereby the measure can be flexibly taken in accordance with such change.

Furthermore, in the stacked package 10, a measure is taken for warp of the tape substrate 9 of the second semiconductor package 14. FIG. 8 shows a case that the measure for warp is taken for the back surface 9b of the tape substrate 9 (the embodiment), and a case that the measure for warp is not taken (comparative example), and FIG. 9 shows a measure for warp of the main surface 9a of the tape substrate 9.

In a tape substrate 9 of the embodiment shown in FIG. 8, a resist film (insulating film) 9h is formed in the periphery of a back surface 9b corresponding to a region outside a chip region 9g of the main surface 9a of the tape substrate. In a tape substrate 9 of the comparative example, the resist film 9h is not formed on a back surface 9b of the tape substrate. The resist film 9h is formed in the region at the back surface side corresponding to the region outside the chip region 9g of the tape substrate 9, thereby tension to the back surface side is induced due to curing shrinkage of the resist film 9h at the back surface side, consequently warp in the region outside the chip region 9g can be suppressed.

Furthermore, as shown in FIG. 9, a dummy pattern (dummy conductor pattern) 9e different from an electrically connected wiring 9d is formed in a region outside the chip region 9g of the main surface 9a of the tape substrate 9.

Thus, stiffness of the region outside the chip region 9g can be improved.

Moreover, the resist film 9h is formed in the region outside the chip region 9g of the main surface 9a of the tape substrate 9, and slits 9f are formed in corners of the resist film 9h.

Thus, tension at the main surface side of the tape substrate 9 can be reduced.

Accordingly, in the tape substrate 9 of the second semiconductor package 14, stiffness of the region outside the chip region 9g can be improved, and tension at the main surface side can be reduced, therefore warp of the tape substrate 9 can be suppressed.

In this way, in the stacked package 10 of the embodiment, a measure is taken for warp in the package substrate 3 of the first semiconductor package 2 or the tape substrate 9 of the second semiconductor package 14. Accordingly, warp of the stacked package 10 can be suppressed.

As a result, occurrence of insufficient connection can be prevented in mounting the stacked package 10 on a mounting substrate, consequently packaging performance of the stacked package 10 can be improved.

Furthermore, in the stacked package 10, as shown in a portion G of FIG. 10, since the second semiconductor package 14 is the fan-out type package, the chip mounting portion is separated from the ball connecting portion, and since the tape substrate 9 is flexible, it is hardly affected by warp, and even if bending stress is applied to it, the stress can be reduced.

Accordingly, connection reliability of the second semiconductor package 14 can be improved.

Next, a measure for heat radiation of the stacked package 10 of the embodiment is described using FIGS. 11 to 18.

In the stacked package 10 of the embodiment, as shown in FIG. 1, the adhesive films (film members) 11 for heat radiation are attached to a surface of the sealing body 6 of the first semiconductor package 2 at the first stage, and the back surface 21b of the second-stage chip 21 of the second semiconductor package 14 and the back surface 25b of the third-stage chip 25 of the stacked second semiconductor packages 14, respectively, and each of the adhesive films 11 for heat radiation is connected also to a substrate at an upper stage side.

Thus, in the stacked package 10 of the embodiment, first, heat resistance when the DSP chip 13a at the first stage generates heat is compared by simulation between a structure (K) where layers are adhered to each other by the adhesive film 11 for heat radiation, and a structure (L) where layers are not adhered and an air gap portion 18 is formed, and an advantageous effect of the film member is described.

FIG. 11 shows an example of a vertical structure of the stacked package 10 and a model structure for calculation. As a condition of the simulation for comparing the heat resistance between them, it is assumed that only one dimension in a vertical direction of the package is given, and radiation area corresponds to the area (7×7 mm=49 mm²) of the DSP chip 13a (diffusion in a lateral direction is not considered). Furthermore, it is assumed that only a surface of the DSP chip 13a is formed as a heating element, and parallel connection of heat transfer in downward and upward directions is the whole heat resistance (θjc) (θjc=(θ1×θ2)/(θ1+θ2), θ1 is total heat resistance in the upward direction of the chip, and θ2 is total heat resistance in the downward direction of the chip).

In the structure shown in FIG. 11, the semiconductor chip 1 of the first semiconductor package 2 is in a structure where it is subjected to underfill connection to the package substrate 3 by the NCP 17. In the structure of FIG. 11, H shows an upward radiation path, I shows a downward radiation path, and J shows a heating portion respectively.

Results of performing simulation to the structure (K) where layers are adhered to each other by the adhesive film 11 for heat radiation, and the structure (L) where layers are not adhered and the air gap portion 18 is formed are shown in FIGS. 12 and 13, respectively. FIG. 12 shows a result of simulation to the structure (K) where layers are adhered to each other by the adhesive film 11 for heat radiation, and in this case, the whole heat resistance (θjc) is θjc=2.51° C./W.

On the other hand, FIG. 13 shows a simulation result of the structure (L) where layers are not adhered and the air gap portion 18 is formed, and in this case, the whole heat resistance (θjc) is θjc=2.83° C./W.

From comparison between two kinds of the whole heat resistance (θjc),a result of no significant difference between the structure (K) and the structure (L) was obtained in heat generation of the DSP chip 13a at the first stage.

Next, heat resistance when the third-stage chip 25 (DRAM chip) of the second semiconductor package 14 at the third stage generates heat is compared by simulation between the structure (K) where layers are adhered to each other by the adhesive film 11 for heat radiation, and the structure (L) where layers are not adhered and the air gap portion 18 is formed, and an advantageous effect of the film member is described.

FIG. 14 shows an example of a vertical structure of the stacked package 10 and a model structure for calculation. As a condition of the simulation of comparing the heat resistance between them here, first, heat resistance in a vertical direction of the three-stage chip 25 is calculated. Heat radiation area at that time is assumed to correspond to area (7×7 mm=49 mm²) of the third-stage chip 25. Moreover, heat resistance in a downward direction from the solder balls 15 via electrode wiring of the tape substrate 9 of the second semiconductor package 14 at the third stage is calculated. Furthermore, it is assumed that parallel connection of heat resistance in downward and upward directions of a chip and heat resistance via the solder balls is the whole heat resistance (θjc) (θjc=(θ1×θ2×θ3)/( (θ1×θ2)+(θ2×θ3)+(θ3×θ1)) , θ1 is total heat resistance in the upward direction of the chip, θ2 is total heat resistance in the downward direction of the chip, and θ3 is total heat resistance of an electrode portion).

While a structure shown in FIG. 14 is the same as the structure shown in FIG. 11, M shows a radiation path of the electrode portion.

According to such conditions, simulation was performed to the structure (K) where layers were adhered to each other by the adhesive film 11 for heat radiation, and the structure (L) where layers were not adhered and the air gap portion 18 was formed, and results of the simulation are shown in FIGS. 15 to 18, respectively. FIG. 15 shows a simulation result of heat transfer in a vertical direction of a chip in the structure (K) where layers are adhered to each other by the adhesive film 11 for heat radiation, and furthermore FIG. 16 shows a simulation result of heat resistance of the electrode portion in the structure (K) respectively, and in this case, the whole heat resistance (θjc) is θjc=3.03° C./W.

On the other hand, FIG. 17 shows a simulation result of heat resistance in the vertical direction of the chip in the structure (L) where layers are not adhered and the air gap portion 18 is formed, and furthermore FIG. 18 shows a simulation result of heat transfer of the electrode portion in the structure (L) respectively, and in this case, the whole heat resistance (θjc) is θjc=9.82° C./W.

From comparison between the two kinds of the whole heat resistance (θjc), a result was obtained: heat resistance was decreased to about 2/3 in the structure (K) where layers are adhered to each other by the adhesive film 11 for heat radiation, compared with the structure (L) where layers are not adhered and the air gap portion 18 is formed.

From the simulation results, the adhesive film 11 for heat radiation is attached between respective package layers, thereby when a chip at an upper stage side generates heat, heat radiation of the stacked package 10 can be improved.

However, the adhesive film 11 for heat radiation need not be attached to all the packages. Among a plurality of semiconductor chips, the semiconductor chip 1 incorporated with the many-pin type DSP circuit performs many operations compared with the chips 21, 25 and 26 incorporated with the memory circuit, and therefore generates heat most significantly. Thus, for example, when heat generated from the semiconductor chip 1 at the first stage is not desired to be transferred to a chip at an upper stage side, the adhesive film 11 for heat radiation can not be attached to a surface of the sealing body 6 of the first semiconductor packaged 2 at the first stage, and attached to only a back surface of a chip at the second stage or later. Thus, a circuit of the DRAM chip at the upper stage side can not be affected by heat from the DSP chip 13a at the first stage.

In the stacked package 10 of the embodiment, as another heat radiation measure, as shown in FIG. 19 and FIG. 20, a plurality of thermal via holes 3e as heat radiation via holes are provided in the chip region 3f where the DSP chip 13a of the package substrate 3 at the first stage is mounted, and furthermore a plurality of dummy balls (dummy ball electrodes) 8a to be connected to the thermal via holes 3e are provided on the back surface 3b of the package substrate 3.

Thus, heat generated from the DSP chip 13a can be transferred to the mounting substrate via the thermal via holes 3e and the dummy balls 8a and radiated. Furthermore, in the stacked package 10, the adhesive films 11 for heat radiation are attached between layers of all the packages, thereby heat generated from the chip at the upper stage side can be transferred to the mounting substrate via the adhesive films 11 for heat radiation, in addition, the thermal via holes 3e and the dummy balls 8a, and radiated.

Accordingly, in the stacked package 10, the package substrate 3 as the multilayer organic substrate is disposed at the lowest stage, and the DSP chip 13a is disposed in the chip region 3f of the main surface 3a of the package substrate 3, the DSP chip having many pins and generating large amount of heat, thereby the number of pins of the outer terminals (solder balls 8) can be secured without increasing package size, and furthermore heat radiation can be achieved in the many-pin type chip such as DSP chip 13a which generates large amount of heat.

Next, a method of manufacturing the semiconductor device (stacked package 10) of the embodiment is described.

First, assembling of the first semiconductor package 2 shown in FIG. 21 is described.

First, as shown in step S1, Au stud bump formation is performed. That is, gold bumps 5 are formed on pads (surface electrodes) of each semiconductor chip 1 by stud bumping. However, bump formation is not limited to this, and the gold bumps 5 may be formed by a plating process.

Then, resin coating shown in step S2 is performed. Here, the NCP 17 is coated on each device region of a multi package substrate 19. Furthermore, solder is pre-coated electrodes at a substrate side.

Then, chip mounting shown instep S3 is performed. Here, a plurality of semiconductor chips 1 is mounted on a main surface of the multi package substrate 19 by flip-chip connection. At that time, first, main surfaces 1a of the semiconductor chips 1 are disposed in a manner of facing the multi package substrate 19, and furthermore the semiconductor chips 1 are connected to the electrodes on the substrate by Au to solder connection.

Then, molding shown in step S4 is performed. Here, the semiconductor chips 1 are resin-sealed by resin molding and thus a plurality of sealing bodies 6 are formed on the main surface of the multi package substrate 19. In the embodiment, when the resin molding is performed, as shown in FIG. 7, the semiconductor chip 1 is covered by a cavity 16a of the resin molding die 16, then the sealing resin 12 is injected from a gate 16b in the resin molding die 16, the gate being disposed in a manner of facing the back surface 1b of the semiconductor chip 1, thereby the sealing body 6 is formed. That is, the sealing resin 12 is injected from the gate 16b disposed above the back surface 1b of the semiconductor chip 1 (such a gate 16b is sometimes called top gate), thereby the sealing body 6 is formed.

In this way, the sealing body 6 is formed by resin molding, thereby curing shrinkage of resin is induced during curing of the sealing resin 12, consequently the substrate is pulled to a sealing body side, and therefore warp in a convex direction of the substrate can be suppressed.

Moreover, resin molding is performed in a top gate method where resin is filled from the gate 16b disposed above the back surface 1b of the semiconductor chip 1, thereby a metal portion for separating gate resin can not be formed on the substrate, therefore electrodes for connection of the solder balls of the second semiconductor package 14 at an upper stage side can be formed in a region next to the sealing body 6 on the multi package substrate 19.

Then, solder ball supply shown in step S5 shown in FIG. 21 is performed. That is, a plurality of solder balls 8 are provided in each device region of the back surface of the multi package substrate 19.

Then, individuation by cutting and sorting shown in step S6 are performed. That is, a plurality of first semiconductor packages 2 are cut out by individuation, and sorting is performed to obtain the first semiconductor packages 2 as good packages.

Next, assembling of the second semiconductor package 14 shown in FIG. 22 and FIG. 23 is described.

First, as shown in step S11, Au stud bump formation is performed. That is, gold bumps 5 are formed on pads (surface electrodes) of the different semiconductor chips such as the second-stage chip 21, third-stage chip 25 and fourth stage chip 26 by stud bumping. However, the gold bumps 5 may be formed by the plating process.

Then, chip mounting shown in step S12 is performed. Here, for example, a plurality of second-stage chips 21 as the different semiconductor chips are mounted on a main surface of a flexible, multiple tape substrate 20. At that time, main surfaces 21a of the second-stage chips 21 are disposed in an opposed manner to the main surface of the multiple tape substrate 20, and then the second-stage chips 21 are mounted on the multiple tape substrate 20 by thermocompression bonding of Au to Au or Au to Sn using inner lead bonding (ILB).

Then, sealing shown in step S13 is performed. Here, the underfill resin 7 is supplied into a space between each second-stage chip 21 and the multiple tape substrate 20 for sealing.

Then, solder ball supply shown in step S14 is performed. That is, a plurality of solder balls 15 are provided on areas outside respective chip regions of a back surface of the multiple tape substrate 20. The solder balls 15 to be mounted here are formed of, for example, lead-free solder.

Then, sorting shown in step S15 is performed. Here, as shown in FIG. 23, the packages are subjected to sorting and a test (for example, burn-in test) in a reeled condition. At that time, a sorting test is performed using a plurality of test terminals 20a provided on the multiple tape substrate 20 for determining whether a package is good or not.

Furthermore, the adhesive film 11 for heat radiation is attached to a back surface 21b of a second-stage chip 21 (different semiconductor chip) of a second semiconductor package 14 as good package.

Then, individuation by cutting as shown in step S16 is performed. Here, only packages determined as good packages are cut out, and packages determined as bad packages are not cut out and remained on the multiple tape substrate 20 as it is.

Thus, the second semiconductor package 14 as good package is obtained.

Next, a procedure of stacking the second semiconductor packages 14 on the first semiconductor package 2 is described. Here, as shown in FIG. 24 and FIG. 25, a case that three, second semiconductor packages 14 are sequentially stacked on the first semiconductor package 2 to assemble a stacked package 10 having a four-stage structure in total is described.

First, adhesive attaching shown in step S21 is performed. Here, the adhesive film 11 for heat radiation is attached to a surface of the sealing body 6 of the first semiconductor package 2.

Then, solder paste transfer shown in step S22 is performed. First, solder paste 4 is coated on a surface of a transfer unit 22 using a squeegee 22a, and then the solder balls 15 of the second semiconductor package 14 are contacted to the solder paste 4 so that the solder paste 4 is transferred on the solder balls 15.

Then, stacking shown in step S23 is performed. Here, first, the first semiconductor package 2 is disposed in a carrier jig 23, then the three, second semiconductor packages 14 are sequentially stacked on the first semiconductor package 2 via the solder balls 15 transferred with the solder paste 4.

Then, reflow and cleaning shown in step S24 are performed. Here, collective reflow is performed, so that the solder paste 4 on the solder balls 15 of the second semiconductor package 14 at each stage is melted to electrically connect between the solder balls 15 and electrodes on a substrate at a lower stage.

The number of reflow can be decreased by the collective reflow. Furthermore, the number of steps can be reduced thereby, consequently cost can be reduced.

In collective reflow, the collective reflow may be performed in a manner that a weight 24 is placed on a chip of the second semiconductor package 14 at a top stage, or may be performed in a manner that the weight is not placed. Moreover, the solder balls 15 of the second semiconductor package 14 may be previously mounted on electrodes on a substrate at a lower-stage side.

Then, O/S check (sorting) shown in step S25 is performed. Here, whether each solder ball 15 is connected to the electrode on the substrate at the lower-stage side is confirmed.

Thus, assembling of the stacked package 10 is completed as shown in step S26.

According to the semiconductor device and a method of manufacturing the device of the embodiment, since the sealing body 6 formed by the resin molding in the transfer method is formed on the package substrate 3 of the first semiconductor package 2 at the lowest stage, the curing shrinkage effect of the sealing resin 12 occurs during resin molding, thereby warp of the package substrate 3 can be reduced. As a result, packaging performance can be improved in stacking of packages. That is, board level packaging performance can be improved in a user.

Moreover, since the adhesive films 11 for heat radiation are disposed on the surface of the sealing body 6 on the package substrate 3 of the first semiconductor package 2 at the lowest stage, and the back surfaces of the different semiconductor chips such as the second-stage chip 21 and the third-stage chip 25 of the second semiconductor packages 14 stacked on the first semiconductor package 2, heat generated from the different semiconductor chip of the package stacked at the upper stage can be transferred from the semiconductor chip to the package at the lower stage directly below the semiconductor chip via the adhesive film 11 for heat radiation without going through the solder balls 15 provided in the periphery of the semiconductor chip. As a result, the heat can be discharged to the mounting substrate, consequently heat radiation can be improved in the stacked package 10.

In the stacked package 10 of the embodiment, since packages are stacked unlike stacking of chips, sorting is easily carried out. Accordingly, only good packages can be stacked.

Furthermore, since each package at a stage is subjected to sorting, and only the good packages are stacked, cost reduction can be realized in the light of a sorting yield. Moreover, since each package is subjected to sorting, sorting of another company's chip can be performed. Therefore, the semiconductor device can be realized even if KGD chips are not used.

While the invention made by the inventors were specifically described according to the embodiment of the invention hereinbefore, the invention is not limited to the embodiment of the invention, and it is obvious that the invention can be variously altered or modified within a scope without departing from the gist of the invention.

For example, while the case of the stacked package 10 in which packages are stacked in four stages in total was described in the embodiment, the packages may be stacked in any number of stages if it is two or more.

The embodiment of the invention is preferably used for a semiconductor device in a package stacking type and assembling of the semiconductor device.

1. A semiconductor device, comprising:
a wiring substrate having a main surface and a back surface opposed to the main surface, and having a base material formed of resin,
a semiconductor chip mounted on the main surface of the wiring substrate,
a first sealing body for sealing the semiconductor chip,
a plurality of first ball electrodes provided on the back surface of the wiring substrate,
tape substrates having main surfaces and back surfaces opposed to the main surfaces,
different semiconductor chips mounted on the main surfaces of the tape substrates,
a second sealing body being filled into spaces between the main surfaces of the tape substrates and main surfaces of the different semiconductor chips, and having low viscosity compared with the first sealing body, and
a plurality of second ball electrodes provided on the back surfaces of the tape substrates;
wherein the tape substrates are stacked on the main surface of the wiring substrate via the plurality of second ball electrodes in one or several stages.

2. The semiconductor device according to claim 1:
wherein insulating films are formed on the back surfaces corresponding to regions outside chip regions of the main surfaces of the tape substrates.

3. The semiconductor device according to claim 1:
wherein dummy conductor patterns are formed in regions outside chip regions of the main surfaces of the tape substrates.

4. The semiconductor device according to claim 1:
wherein insulating films are formed in regions outside chip regions of the main surfaces of the tape substrates, and slits are formed in the insulating films on the main surfaces.

5. The semiconductor device according to claim 1:
wherein the plurality of second ball electrodes have third ball electrodes to be electrically connected to the main surface of the wiring substrate, and fourth ball electrodes to be electrically connected to the main surfaces of the tape substrates, and a diameter of the third ball electrodes is larger than a diameter of the fourth ball electrodes.

6. The semiconductor device according to claim 1:
wherein the plurality of second ball electrodes have third ball electrodes to be electrically connected to the main surface of the wiring substrate, and fourth ball electrodes to be electrically connected to the main surfaces of the tape substrates, and the third ball electrodes are formed high compared with the first sealing body, and the fourth ball electrodes are formed low compared with the first sealing body.

7. The semiconductor device according to claim 1:
wherein the wiring substrate has the base material including glass epoxy series resin.

8. The semiconductor device according to claim 1:
wherein the semiconductor chip has a logic circuit, and the different semiconductor chip has a memory circuit.

9. The semiconductor device according to claim 1:
wherein the semiconductor chip and the different semiconductor chips are connected to the wiring substrate in a flip-chip manner.

10. The semiconductor device according to claim 1:
wherein the second sealing body is filled in a space between the main surface of the wiring substrate and the main surface of the semiconductor chip.

11. The semiconductor device according to claim 1:
wherein the wiring substrate has many wiring lines compared with the tape substrates.

12. A semiconductor device, comprising:
a wiring substrate having a main surface and a back surface opposed to the main surface, and having a base material formed of resin,
a plurality of semiconductor chips mounted on the main surface of the wiring substrate,
a first sealing body for collectively sealing the plurality of semiconductor chips,
a plurality of first ball electrodes provided on the back surface of the wiring substrate,
tape substrates having main surfaces and back surfaces opposed to the main surfaces,
different semiconductor chips mounted on the main surfaces of the tape substrates,
a second sealing body being filled into spaces between the main surfaces of the tape substrates and main surfaces of the different semiconductor chips, and having low viscosity compared with the first sealing body, and
a plurality of second ball electrodes provided on the back surfaces of the tape substrates;
wherein the tape substrates are stacked on the main surface of the wiring substrate via the plurality of second ball electrodes in one or several stages.

13. A semiconductor device, comprising:
a wiring substrate having a main surface and a back surface opposed to the main surface, and having a base material formed of resin,
a semiconductor chip mounted on the main surface of the wiring substrate,
a plurality of first ball electrodes provided on the back surface of the wiring substrate,
tape substrates having main surfaces and back surfaces opposed to the main surfaces,
different semiconductor chips mounted on the main surfaces of the tape substrates, and
a plurality of second ball electrodes provided on the back surfaces of the tape substrates;
wherein the tape substrates are stacked on the main surface of the wiring substrate via the plurality of second ball electrodes in several stages, and
a film member is attached to back surfaces of the different semiconductor chips.

14. The semiconductor device according to claim 13:
wherein a first sealing body for sealing the semiconductor chip is provided on the main surface of the wiring substrate, and the film member is attached to a surface of the first sealing body.

15. The semiconductor device according to claim 13:
wherein a plurality of via holes for heat radiation are provided in a chip region of the wiring substrate, and a plurality of dummy ball electrodes to be connected to the via holes for heat radiation are provided in the back surface of the wiring substrate.

16-18. (canceled)
